(19) United States
(12) Patent Application Publication
(10) Pub. No.: US 2026/0304681 A1
(43) Pub. Date: Oct. 1, 2026

(54) SLIDING RAIL DEVICE

(71) Applicant: FOSITEK CORPORATION, New Taipei City (TW)

(72) Inventors: Kuan-Wei CHEN, New Taipei City (TW); Kai-Hung LIN, New Taipei City (TW)

(73) Assignee: FOSITEK CORPORATION, New Taipei City (TW)

(21) Appl. No.: 19/241,672

(22) Filed: Jun. 18, 2025

(30) Foreign Application Priority Data
Mar. 28, 2025 (TW) 114112021

(51) Int. Cl. H05K 7/18; A47B 88/423; H05K 7/14

(52) U.S. Cl. CPC H05K 7/183; A47B 88/423; H05K 7/1489

(57) ABSTRACT

A sliding rail device includes an exterior frame, an outer rail, an intermediate rail, and a block mechanism that has a position member, two block members defining a blocker groove, a link piece having a limit protrusion and sleeved on the position member, and a resilient member. When the intermediate rail is moved relative to the outer rail in a longitudinal direction, the position member is moved downwardly along the blocker groove under guidance of one of the blocker members, and is consequently adapted to move a linking member downwardly. When the intermediate rail is moved in the longitudinal direction relative to the outer rail, the position member is driven to move downwardly to pass over the limit protrusion against a resilient force of the resilient member to a position below the limit protrusion such that the limit protrusion prevents the position member from moving in a height direction.

### CROSS-REFERENCE TO RELATED APPLICATION

This application claims priority to Taiwanese Invention Patent Application No. 114112021, filed on Mar. 28, 2025, the entire disclosure of which is incorporated by reference herein.

### FIELD

The disclosure relates to a sliding rail device, and more particularly to a sliding rail device with a block mechanism.

### BACKGROUND

A conventional server chassis is mounted to a server rack through a conventional sliding rail device. The conventional sliding rail device includes an outer rail fixed to the server rack, an intermediate rail movably engaged with the outer rail, and an inner rail connected to the server chassis. During maintenance or change of the server chassis, the server chassis may be pulled out from the server rack through operation of the conventional sliding rail device. However, when there are several other server chassis mounted to the server rack through other conventional sliding rail devices, and when one of the server chassis is pulled out, the corresponding conventional sliding rail device is unable to prevent another server chassis from moving outwardly on its own. Hence, there is room for improvement.

### SUMMARY

Therefore, an object of the disclosure is to provide a sliding rail device that can alleviate at least one of the drawbacks of the prior art.

According to the disclosure, the sliding rail device is adapted to be mounted to a server rack and connected to a linking member. The sliding rail device includes an exterior frame, an outer rail, an intermediate rail, and a block mechanism. The exterior frame is adapted to be fixed to the server rack, and has first and second ends, a frame surface, an installation surface, and an exterior groove. The first end is opposite to the second end in a longitudinal direction. The installation surface is opposite to the frame surface and adapted to face the server rack. The frame surface and the installation surface extend between the first and second ends. The exterior groove extends through the frame surface and the installation surface. The outer rail is disposed on the frame surface, and has a first outer rail surface, a second outer rail surface, and a connection groove. The second outer rail surface is opposite to the first outer rail surface and faces the frame surface. The connection groove extends through the first outer rail surface and the second outer rail surface, and corresponds in position to the exterior groove. The intermediate rail is movably engaged with the outer rail, and has an intermediate rail surface facing the outer rail. The block mechanism has a position member, two blocker members, a link piece, and a resilient member. The position member movably extends through the exterior groove and the connection groove, and is adapted to be fixed to the linking member. The blocker members are disposed on the intermediate rail surface, and are spaced apart from each other in a height direction perpendicular to the longitudinal direction. The link piece is sleeved on the position member. The resilient member extends in the longitudinal direction, and is connected to the installation surface and the link piece. Each of the blocker members has a blocker protrusion. Each of the blocker protrusions has an abutment surface extending in the height direction, and an inclined surface inclined relative to the height direction. The inclined surfaces of the blocker protrusions of the blocker members cooperatively define a blocker groove therebetween. The blocker groove extends obliquely relative to the longitudinal direction with an end of the blocker groove that is closer to the first end of the exterior frame being higher than an opposite end of the blocker groove that is farther from the first end of the exterior frame. The position member is engaged with and movable along the blocker groove. The link piece has a link groove, and a limit protrusion extending opposite to the longitudinal direction and into the link groove. The position member extends movably into the link groove. The resilient member resiliently biases the limit protrusion to abut against the position member. When the intermediate rail is moved in the longitudinal direction relative to the outer rail, the position member is moved downwardly along the blocker groove under guidance of one of the blocker members, and is consequently adapted to move the linking member downwardly and adapted to drive another sliding rail device that is connected to the linking member and that is identical to the sliding rail device to move synchronously in a manner where the position member of the another sliding rail device is moved downwardly to be adjacent to the abutment surface of one of the blocker protrusions of the another sliding rail device so as to prevent movement of the intermediate rail of the another sliding rail device relative to the outer rail of the another sliding rail device. When the intermediate rail is moved in the longitudinal direction relative to the outer rail, the position member is driven to move downwardly to pass over the limit protrusion against a resilient force of the resilient member to a position below the limit protrusion such that the limit protrusion prevents the position member from moving in the height direction.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating an embodiment of a sliding rail device according to the disclosure.

FIG. 2 is a side view illustrating two sliding rail devices of the disclosure being connected to a linking member.

FIG. 3 is a partially exploded perspective view of the embodiment.

FIG. 4 is a fragmentary exploded perspective view of an exterior frame and a block mechanism of the embodiment.

FIG. 5 is a rear view of an intermediate rail of the embodiment.

FIG. 6 is a fragmentary sectional view of the embodiment taken along line VI-VI in FIG. 1, and the intermediate rail and an inner rail are omitted.

FIG. 7 is a fragmentary schematic side view of the intermediate rail, illustrating a position portion of a position member in a starting position.

FIG. 8 is a fragmentary rear view of the exterior frame, illustrating the position portion in the starting position.

FIG. 9 is a fragmentary schematic side view of the intermediate rail, illustrating the position portion being moved downwardly along a blocker groove by blocker members.

FIG. 10 is a fragmentary rear view of the exterior frame, illustrating the position portion being moved downwardly.

FIG. 11 is a fragmentary schematic side view, illustrating a position portion of a position member of another sliding rail device being adjacent to an abutment surface of a blocker protrusion thereof.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

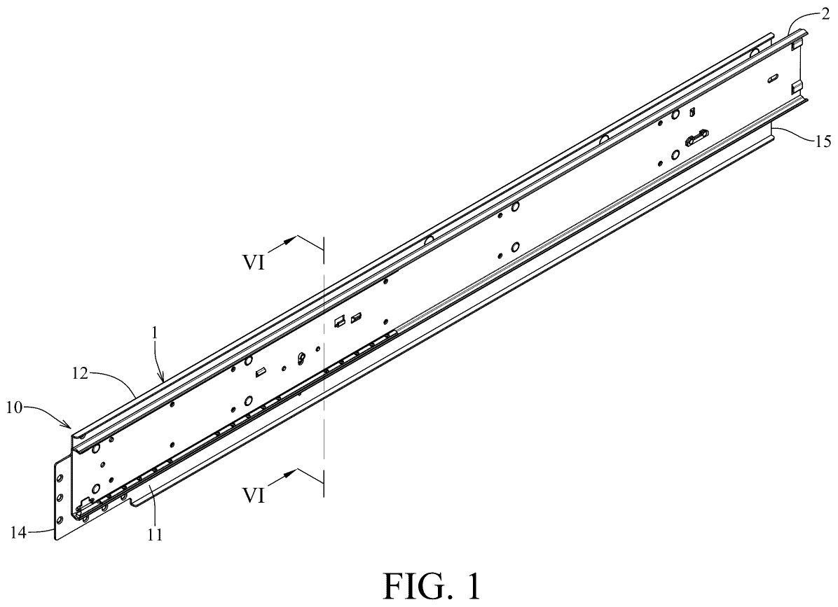

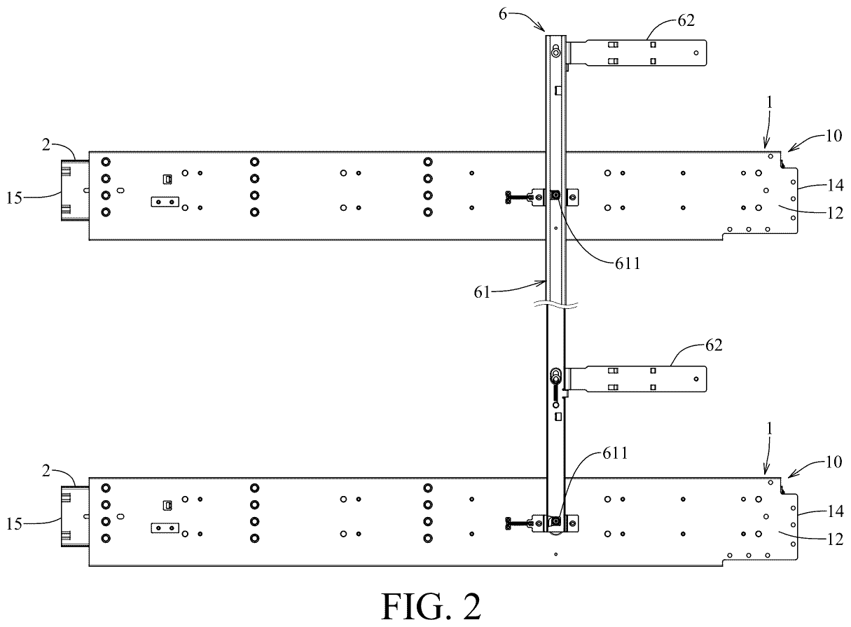

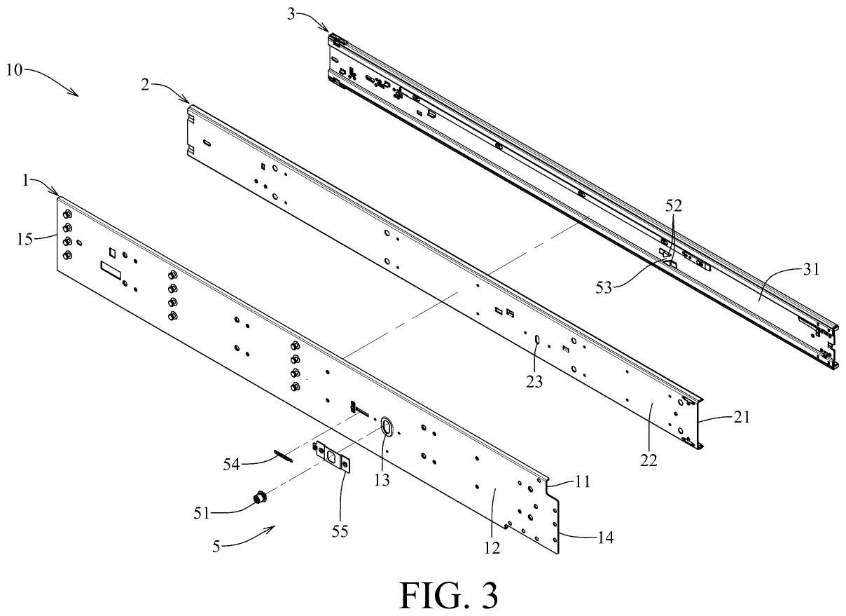

Referring to FIGS. 1 to 3, an embodiment of a sliding rail device 10 according to the disclosure is adapted to be mounted to a server rack (not shown) and connected to a linking member 6. The linking member 6 has a link rod 61 extending in a height direction, and two link plates 62 spaced apart from each other in the height direction and extending in a longitudinal direction perpendicular to the height direction. Each of the link plates 62 is connected to the link rod 61, and is mounted to the server rack. The link rod 61 has two link holes 611. The sliding rail device 10 includes an exterior frame 1, an outer rail 2, an intermediate rail 3, an inner rail (not shown), and a block mechanism 5.

The exterior frame 1 is adapted to be fixed to the server rack, and has first and second ends 14, 15, a frame surface 11, an installation surface 12 opposite to the frame surface 11 and adapted to face the server rack, and an exterior groove 13. The first end 14 is opposite to the second end 15 in the longitudinal direction. The frame surface 11 and the installation surface 12 extend between the first and second ends 14, 15. The exterior groove 13 extends through the frame surface 11 and the installation surface 12. The outer rail 2 is disposed on the frame surface 11, and has a first outer rail surface 21, a second outer rail surface 22 opposite to the first outer rail surface 21 and facing the frame surface 11, and a connection groove 23 extending through the first outer rail surface 21 and the second outer rail surface 22. The connection groove 23 corresponds in position to the exterior groove 13. The intermediate rail 3 is movably engaged with the outer rail 2, and has an intermediate rail surface 31 facing the outer rail 2. The inner rail is movably engaged with the intermediate rail 3, and adapted to be mounted to a chassis (not shown).

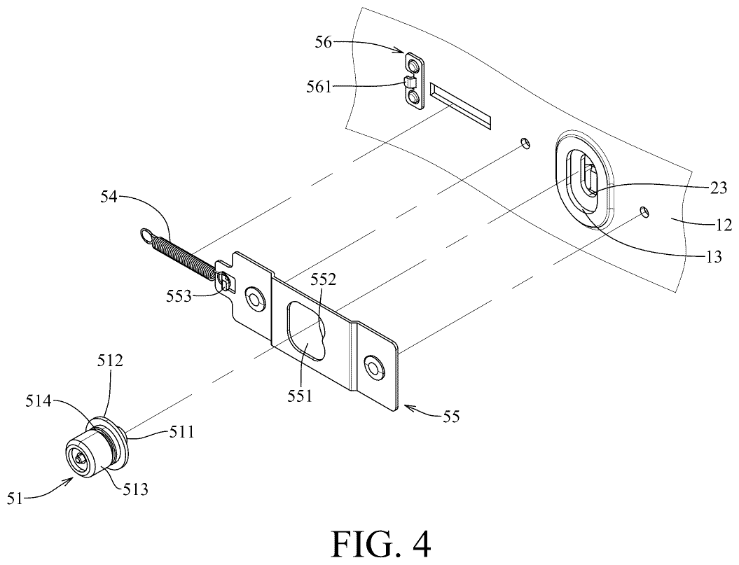

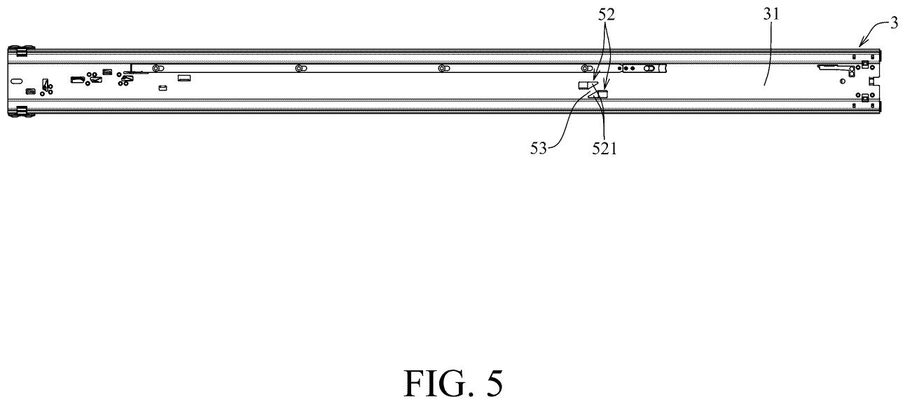

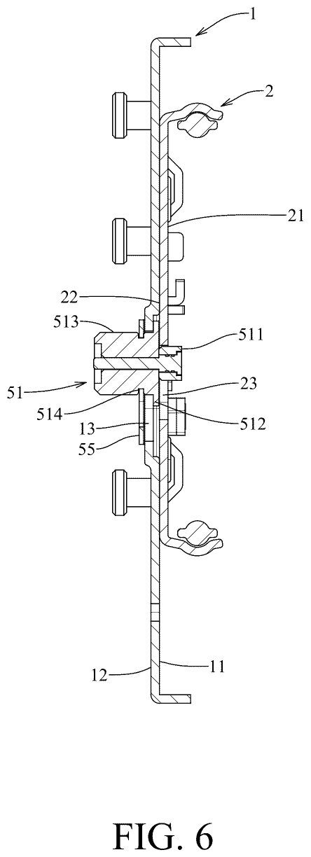

Referring to FIGS. 4 to 7, the block mechanism 5 has a position member 51 movably extending through the exterior groove 13 and the connection groove 23, and adapted to be fixed to the linking member 6, two blocker members 52 disposed on the intermediate rail surface 31, and spaced apart from each other in the height direction, a link piece 55 sleeved on the position member 51, a resilient member 54 extending in the longitudinal direction and connected to the installation surface 12 and the link piece 55, and a fixed member 56 disposed on the installation surface 12. One of the blocker members 52 is disposed higher than another one of the blocker members 52 in the height direction. The position member 51 has a position portion 511 movably extending through the exterior groove 13 and the connection groove 23, an abutment portion 512 extending from the position portion 511 and abutting against the second outer rail surface 22, a connection portion 513 connected to the abutment portion 512 and adapted to be engaged with one of the link holes 611 so as to be fixed to the linking member 6, and a hook groove 514 formed in the connection portion 513. The position portion 511 and the connection portion 513 are cylinders, and the abutment portion 512 is a circular plate. A diameter of the position portion 511 is smaller than a diameter of the connection portion 513, and the diameter of the connection portion 513 is smaller than a diameter of the abutment portion 512. Each of the blocker members 52 has a blocker protrusion 521. Each of the blocker protrusions 521 has an abutment surface extending in the height direction, and an inclined surface inclined relative to the height direction. The inclined surfaces of the blocker protrusions 521 of the blocker members 52 cooperatively define a blocker groove 53 therebetween. The blocker groove 53 extends obliquely relative to the longitudinal direction with an end of the blocker groove 53 that is closer to the first end 14 of the exterior frame 1 being higher than an opposite end of the blocker groove 53 that is farther from the first end 14 of the exterior frame 1. The position member 51 is engaged with and movable along the blocker groove 53.

The resilient member 54 is a tension spring, and has two opposite ends. The link piece 55 engages the hook groove 514 and is disposed on the installation surface 12. The link piece 55 has a link groove 551, a limit protrusion 552 that extends opposite to the longitudinal direction and into the link groove 551, and a first hook 553 that is connected to one of the ends of the resilient member 54. The fixed member 56 includes a second hook 561 that is connected to another one of the ends of the resilient member 54. The position member 51 extends movably into the link groove 551. The resilient member 54 resiliently biases the limit protrusion 552 to abut against the position member 51.

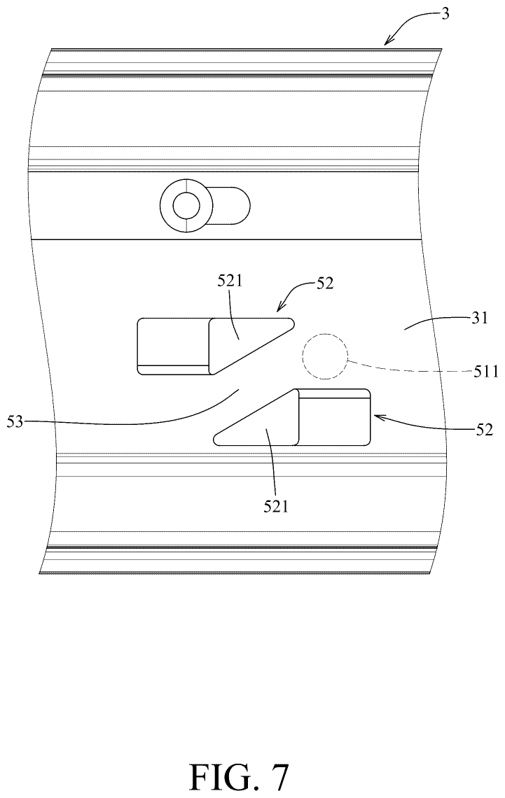

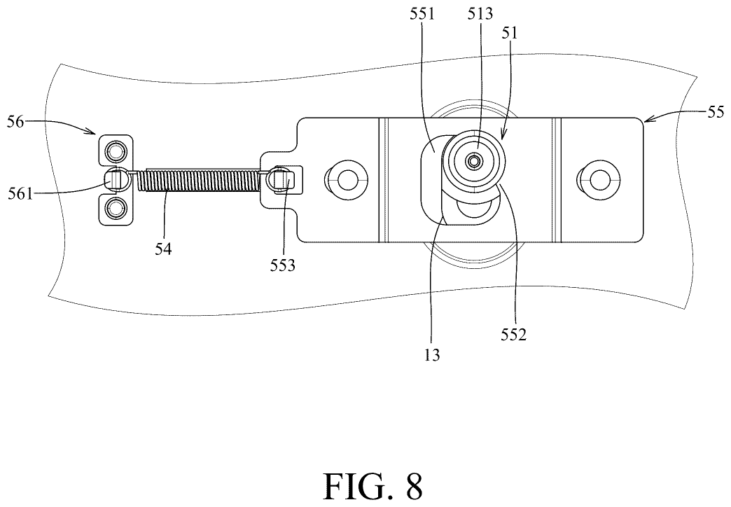

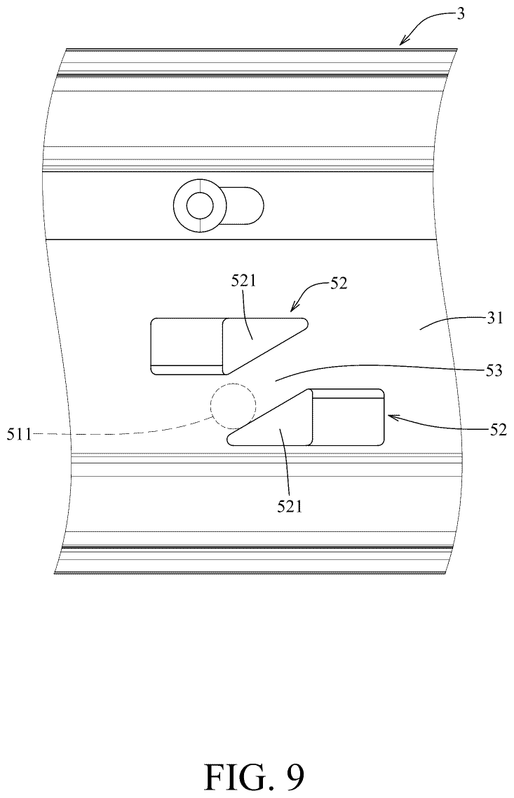

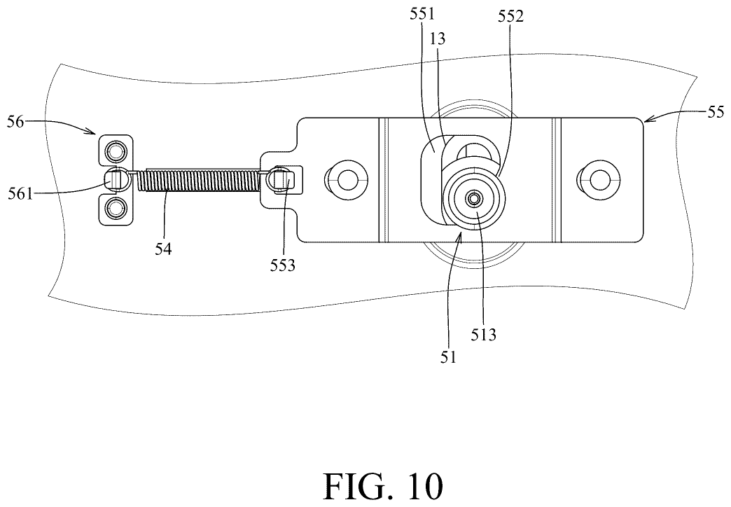

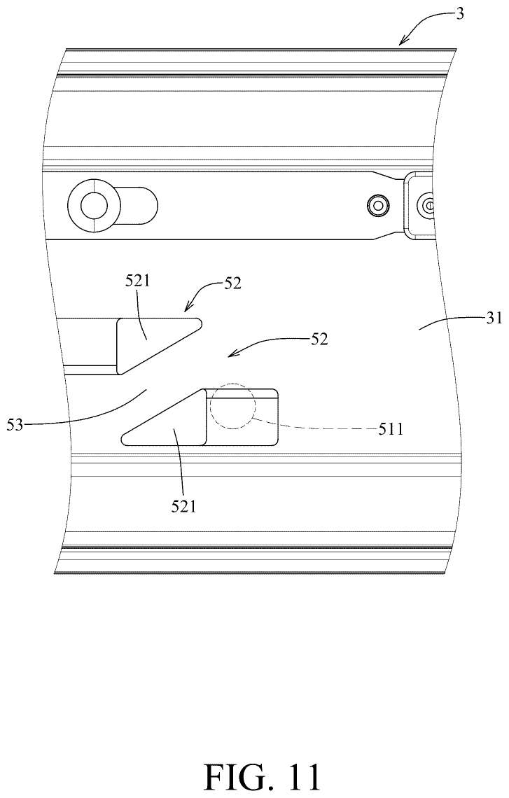

Referring to FIGS. 7 to 10, when the position member 51 is at a starting position (see FIGS. 7 and 8), the position portion 511 is disposed above the another one of the block members 52 (i.e., the lower one of the block members 52); in other words, the position portion 511 is disposed at the end of the blocker groove 53 that is closer to the first end 14 of the exterior frame 1. When the server chassis is pulled out from the server rack, the inner rail is driven to move the intermediate rail 3 in the longitudinal direction relative to the outer rail 2, and the position portion 511 of the position member 51 is moved downwardly along the blocker groove 53 under guidance of the one of the blocker members 52 (i.e., the upper one of the block members 52, see FIG. 9). Since the connection portion 513 is fixed to the linking member 6, the position member 51 is consequently adapted to move the linking member 6 downwardly and adapted to drive another sliding rail device 10 that is connected to another link hole 611 of the linking member 6 and that is identical to the sliding rail device 10 to move synchronously in a manner where the position member 51 of the another sliding rail device 10 is moved downwardly to be adjacent to the abutment surface of the blocker protrusion 521 of the another one of the blocker members 52 of the another sliding rail device 10 (see FIG. 11) so as to prevent movement of the intermediate rail 3 of the another sliding rail device 10 relative to the outer rail 2 of the another sliding rail device 10, thereby preventing the another sliding rail device 10 from unexpectedly moving outwards. At this time, the position member 51 is driven to move downwardly to pass over the limit protrusion 552 against a resilient force of the resilient member 54 to a position below the limit protrusion 552 (see FIG. 10) such that the limit protrusion 552 prevents the position member 51 from moving in the height direction. By virtue of the configuration of the limit protrusion 552, during movement of the intermediate rail 3 in the longitudinal direction relative to the outer rail 2, the limit protrusion 552 consistently prevents the position member 51 from moving in the height direction, which ensures that the linking member 6 is moved downwardly so that the blocker protrusion 521 of the another one of the blocker members 52 of the another sliding rail device 10 is blocked by the position portion 511 of the another sliding rail device 10 to prevent the intermediate rail 3 of the another sliding rail device 10 from moving relative to the outer rail 2 of the another sliding rail device 10. When the server chassis is pushed back into the server rack, the inner rail is driven to move the intermediate rail 3 in a direction opposite to the longitudinal direction relative to the outer rail 2, and the position portion 511 of the position member 51 is moved upwardly along the blocker groove 53 under guidance of the another one of the blocker members 52 towards the starting position, which drives the linking member 6 to move upwardly. Consequentially, the linking member 6 moves the position portion 511 of the another sliding rail device 10 towards the starting position, so that the position portion 511 of the another sliding rail device 10 no longer blocks the blocker protrusion 521 of the another one of the blocker members 52 of the another sliding rail device 10. Hence, the another sliding rail device 10 will not move outwardly during use of the sliding rail device 10. It should be noted that, when the server chassis is pushed back into the server rack, the position member 51 is driven to move upwardly to pass over the limit protrusion 552 against the resilient force of the resilient member 54 to the starting position above the limit protrusion 552, which facilitates movement of the position member 51 to the starting position.

In conclusion, when the intermediate rail 3 is moved in the longitudinal direction relative to the outer rail 2, the position portion 511 of the position member 51 is moved downwardly along the blocker groove 53 under guidance of the one of the blocker members 52, and is consequently adapted to move the linking member 6 downwardly and is adapted to drive another sliding rail device 10 that is connected to the linking member 6 and that is identical to the sliding rail device 10 to move synchronously in a manner where the position portion 511 of the position member 51 of the another sliding rail device 10 is moved downwardly to be adjacent to the abutment surface of one of the blocker protrusions 521 of the another sliding rail device 10 so as to prevent movement of the intermediate rail 3 of the another sliding rail device 10 relative to the outer rail 2 of the another sliding rail device 10. Hence, the another sliding rail device 10 will not move outwardly during use of the sliding rail device 10, and the objective of the disclosure is achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A sliding rail device adapted to be mounted to a server rack and connected to a linking member, said sliding rail device comprising:
an exterior frame that is adapted to be fixed to the server rack, and that has
first and second ends, said first end being opposite to said second end in a longitudinal direction;
a frame surface,
an installation surface opposite to said frame surface and adapted to face the server rack, said frame surface and said installation surface extending between said first and second ends, and
an exterior groove extending through said frame surface and said installation surface;
an outer rail that is disposed on said frame surface, and that has a first outer rail surface, a second outer rail surface opposite to said first outer rail surface and facing said frame surface, and a connection groove extending through said first outer rail surface and said second outer rail surface, and corresponding in position to said exterior groove;
an intermediate rail that is movably engaged with said outer rail, and that has an intermediate rail surface facing said outer rail; and
a block mechanism that has
a position member movably extending through said exterior groove and said connection groove, and adapted to be fixed to the linking member,
two blocker members disposed on said intermediate rail surface, and spaced apart from each other in a height direction perpendicular to the longitudinal direction,
a link piece sleeved on said position member, and
a resilient member extending in the longitudinal direction, and connected to said installation surface and said link piece;
wherein each of said blocker members has a blocker protrusion, each of said blocker protrusions having an abutment surface extending in the height direction, and an inclined surface inclined relative to the height direction, said inclined surfaces of said blocker protrusions of said blocker members cooperatively defining a blocker groove therebetween, said blocker groove extending obliquely relative to the longitudinal direction with an end of said blocker groove that is closer to said first end of said exterior frame being higher than an opposite end of said blocker groove that is farther from said first end of said exterior frame, said position member being engaged with and movable along said blocker groove;
wherein said link piece has a link groove, and a limit protrusion extending opposite to the longitudinal direction and into said link groove, said position member extending movably into said link groove, said resilient member resiliently biasing said limit protrusion to abut against said position member;
wherein, when said intermediate rail is moved in the longitudinal direction relative to said outer rail, said position member is moved downwardly along said blocker groove under guidance of one of said blocker members, and is consequently adapted to move the linking member downwardly and adapted to drive another sliding rail device that is connected to the linking member and that is identical to said sliding rail device to move synchronously in a manner where the position member of the another sliding rail device is moved downwardly to be adjacent to the abutment surface of one of the blocker protrusions of the another sliding rail device so as to prevent movement of the intermediate rail of the another sliding rail device relative to the outer rail of the another sliding rail device; and
wherein, when said intermediate rail is moved in the longitudinal direction relative to said outer rail, said position member is driven to move downwardly to pass over said limit protrusion against a resilient force of said resilient member to a position below said limit protrusion such that said limit protrusion prevents said position member from moving in the height direction.

2. The sliding rail device as claimed in claim 1, wherein said link piece further has a first hook, said resilient member having two opposite ends, said first hook being connected to one of said ends of said resilient member.

3. The sliding rail device as claimed in claim 2, wherein said block mechanism further includes a fixed member disposed on said installation surface, said fixed member including a second hook that is connected to another one of said ends of said resilient member.

4. The sliding rail device as claimed in claim 1, wherein said position member has a position portion movably extending through said exterior groove and said connection groove, an abutment portion extending from said position portion and abutting against said second outer rail surface, and a connection portion connected to said abutment portion and adapted to be fixed to the linking member.

5. The sliding rail device as claimed in claim 4, wherein said position member further has a hook groove that is formed in said connection portion, said link piece engaging said hook groove and being disposed on said installation surface.
